(19) United States
(12) Patent Application Publication
(10) Pub. No.: US 2023/0095515 A1
(43) Pub. Date: Mar. 30, 2023

(54) ELECTRIC MOTOR DRIVE WITH GALLIUM NITRIDE POWER SWITCHES HAVING LOW-SIDE SHORT CIRCUIT SAFE STATE

(71) Applicant: MAGNA INTERNATIONAL INC., Aurora (CA)

(72) Inventors: Michael NEUDORFHOFER, Hofkirchen (AT); Martin WINTER, Dietach (AT); Wolfgang BAECK, Sankt Valentin (AT)

(21) Appl. No.: 17/795,562

(22) PCT Filed: Jan. 29, 2021
(86) PCT No.: PCT/CA2021/050099

§ 371 Date: Jul. 27, 2022

Related U.S. Application Data
(60) Provisional application No. 62/968,607, filed on Jan. 31, 2020.

(51) Int. Cl. H03K 17/687; H02P 29/028; H02M 7/537; H02P 3/22

(52) U.S. Cl. CPC H03K 17/687; H02P 29/028; H02M 7/537; H02P 3/22; H03K 2017/6875; H03K 2217/0063; H03K 2217/0072

(57) ABSTRACT

A switching circuit of a motor drive includes a high-side switch configured to selectively conduct current between a DC positive conductor and an output conductor, and a low-side switch configured to selectively conduct current between the output conductor and a DC negative conductor. The high-side switch comprises a depletion mode (D-Mode) gallium nitride (GaN) high-electron-mobility transistor (HEMT) and a Si-FET in a cascaded configuration, and the low-side switch comprises a D-Mode GaN HEMT. This arrangement can provide a safe state operation in which the switching circuit provides a default condition providing electrical continuity between the DC negative conductor and the output conductor and providing electrical isolation between the DC positive conductor and the output conductor in the event of a loss of control signals.

### CROSS-REFERENCE TO RELATED APPLICATIONS

This PCT International Patent Application claims the benefit of U.S. Provisional Patent Application Ser. No. 62/968,607 filed on Jan. 31, 2020, and titled “Electric Motor Drive With Gallium Nitride Power Switches Having Low-Side Short Circuit Safe State”, the entire disclosure of which is hereby incorporated by reference.

### FIELD

The present disclosure relates generally to power switches in a drive circuit for generating an alternating current (AC) power to supply an electric motor. More specifically, the present disclosure relates to power switches that are configured to have a safe state in which the conductor supplying the electric motor is automatically short-circuited to a low-side conductor.

### BACKGROUND

AC motor drives are used in a variety of applications to supply power to permanent-magnet synchronous motors. Conventional AC motor drives may be configured to short-circuit all motor phases in a safe state to protect the semiconductors from overvoltage. To accomplish such a safe state, switches in a high-side path of the motor drive are opened and switches in a low-side path are closed.

A phase switch circuit may be designed to ensure that each motor phase is driven to the safe state by causing switches in the low-side path to default to a closed or conductive condition and by causing switches in the high-side path to default to an open or non-conductive condition in the event of a sudden loss of control signals.

### SUMMARY

The present disclosure provides a switching circuit including a high-side switch configured to selectively conduct current between a DC positive conductor and an output conductor, and a low-side switch configured to selectively conduct current between the output conductor and a DC negative conductor. At least one of the high-side switch or the low-side switch comprises a high-electron-mobility transistor (HEMT) and a second transistor in a cascaded configuration.

### BRIEF DESCRIPTION OF THE DRAWINGS

Further details, features and advantages of designs of the invention result from the following description of embodiment examples in reference to the associated drawings.

FIG. 1 a block diagram of a system in accordance with the present disclosure; and

FIG. 2 shows a schematic diagram of a switching circuit in accordance with some embodiments of the present disclosure.

### DETAILED DESCRIPTION

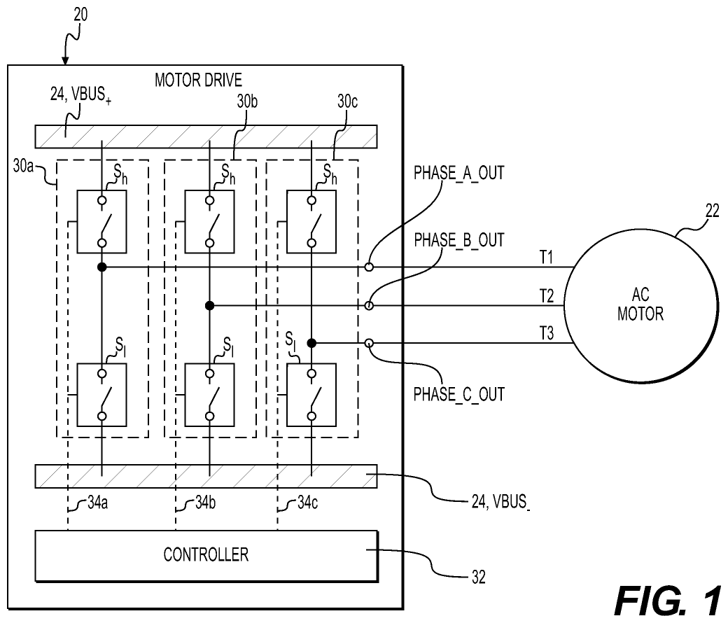

Referring to the Figures, wherein like numerals indicate corresponding parts throughout the several views, a motor drive 20 for providing AC power to an electric motor 22 is disclosed. As best shown in FIG. 1, the motor drive 20 includes a DC bus 24 comprising a DC negative conductor VBUS₋ and a DC positive conductor VBUS₊ having a high DC voltage with respect to the DC negative conductor VBUS₋. The DC negative conductor VBUS₋ may also be called a “low-side path”, and the DC positive conductor VBUS₊ may also be called a “high-side path”. The DC bus 24 is preferably energized to about 400 VDC to 500 VDC, although other voltages may be used depending on the supply available and/or the requirements of a given application.

As also shown in FIG. 1, a DC supply 26 energizes the DC bus 24 with the high DC voltage via DC supply leads 28. The DC supply 26 may be, for example, a battery pack, a DC generator, or a rectifier producing the high DC voltage from an AC source such as a utility line, or from an AC generator. The motor drive 20 includes a first output terminal PHASE_A_OUT for connection of a first motor lead T1 to supply AC power to the electric motor 22, a second output terminal PHASE_B_OUT for connection of a second motor lead T2 to supply AC power to the electric motor 22, and a third output terminal PHASE_C_OUT for connection of a third motor lead T3 to supply AC power to the electric motor 22. In the example embodiment shown in the figures, a three-phase electric motor 22 is used; however, other numbers of phases may be used, such as a single-phase motor or one having six or more phases.

The motor drive 20 includes a first phase switch 30a for selectively connecting the first output terminal PHASE_A_OUT to either of the DC positive conductor VBUS₊ or the DC negative conductor VBUS₋ of the DC bus 24 at any given time. The motor drive 20 also includes a second phase switch 30b for selectively connecting the second output terminal PHASE_B_OUT to either of the DC positive conductor VBUS₊ or the DC negative conductor VBUS₋ of the DC bus 24 at any given time. The motor drive 20 also includes a third phase switch 30c for selectively connecting the third output terminal PHASE_C_OUT to either of the DC positive conductor VBUS₊ or the DC negative conductor VBUS₋ of the DC bus 24 at any given time. Each of the phase switches 30a, 30b, 30c includes a high-side switch Sₕ configured to selectively conduct current between the DC positive conductor VBUS₊ and a corresponding one of the output terminals PHASE_A_OUT, PHASE_B_OUT, PHASE_C_OUT. Each of the phase switches 30a, 30b, 30c also includes a low-side switch Sₗ configured to selectively conduct current between the DC negative conductor VBUS₋ and the corresponding one of the output terminals PHASE_A_OUT, PHASE_B_OUT, PHASE_C_OUT.

A controller 32 coordinates operation of the phase switches 30a, 30b, 30c by providing control signals upon control lines 34a, 34b, 34c.

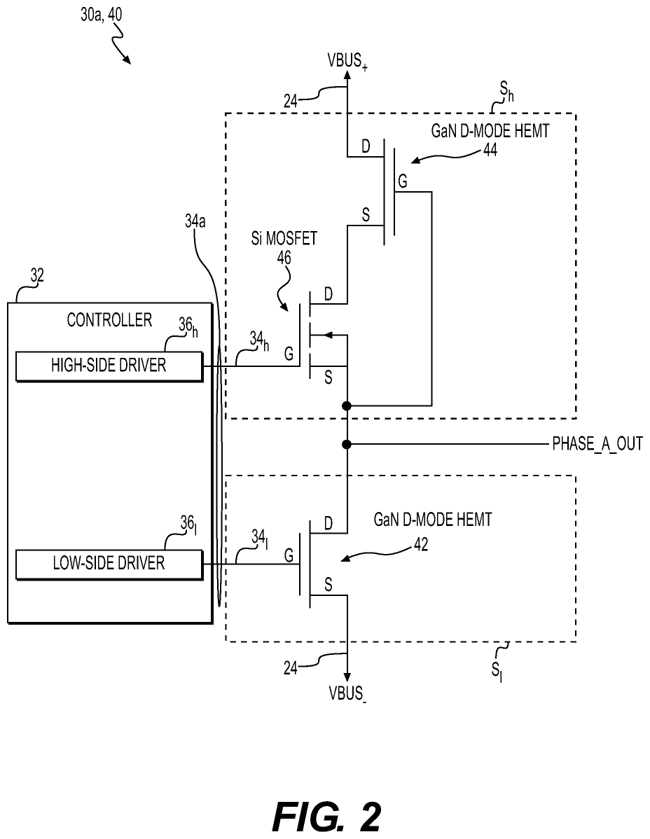

FIG. 2 shows a schematic diagram of a switching circuit 40 in accordance with some embodiments of the present disclosure. The switching circuit 40 of FIG. 2 may be used as any of the phase switches 30a, 30b, 30c of the motor drive 20. The switching circuit 40 of FIG. 2 may be used in other applications, such as in an inverter to supply one or more different AC loads.

The switching circuit 40 includes a high-side switch Sₕ configured to selectively conduct current between a DC positive conductor VBUS₊ and an output conductor PHASE_A_OUT. The switching circuit 40 also includes a low-side switch S₁ configured to selectively conduct current between the output conductor PHASE_A_OUT and a DC negative conductor VBUS₋, where the DC positive conductor VBUS₊ at a higher voltage potential than the DC negative conductor VBUS₋. At least one of the high-side switch Sₕ or the low-side switch Sₗ comprises a high-electron-mobility transistor (HEMT) 44 and a second transistor 46 in a cascaded configuration. The high-side switch Sₕ in the example circuit shown in FIG. 2 includes the high-electron-mobility transistor (HEMT) 44 and the second transistor 46 in the cascaded configuration, although in other embodiments, the high-electron-mobility transistor (HEMT) 44 and the second transistor 46 may be part of the low-side switch Sₗ.

The HEMT 44 of the high-side switch Sₕ includes a depletion mode (D-Mode) transistor in the example switching circuit 40 shown in FIG. 2, More specifically, the HEMT 44 of the high-side switch Sₕ includes a depletion mode (D-Mode) gallium nitride (GaN) HEMT. Such a depletion mode transistor defaults to a conductive condition (i.e. to conduct current between the drain and the source thereof in the absence of a control voltage being applied to a gate thereof. Other types of HEMT may be used, such as a silicon carbide (SiC) transistor. The second transistor 46 may be a Silicon (Si)-based field effect transistor (FET), such as a metal-oxide field effect transistor (MOSFET), although the second transistor 46 may be a different type of device, such as a junction device, another type of FET, and/or a silicon controlled rectifier. The cascaded configuration may be a cascode, which may be defined as two-stage amplifier that consists of a common-emitter stage feeding into a common-base stage, or a similar or equivalent arrangement using other devices, such as FETs.

In some embodiments, and as shown in FIG. 2, the cascaded configuration includes a gate G of the HEMT 44 connected to the output conductor PHASE_A_OUT. In some embodiments, and as shown in FIG. 2, the cascaded configuration includes a drain terminal D of the HEMT 44 connected to the DC positive conductor VBUS₊, a source terminal S of the HEMT 44 connected to a drain terminal D of the second transistor 46, and a source terminal S of the second transistor 46 connected to the output conductor PHASE_A_OUT. In some embodiments, the cascaded configuration includes a gate G of the second transistor 46 connected to a control line 36ₕ, 36ₗ for controlling operation of the high-side switch Sₕ or the low-side switch Sₗ. More specifically, and as shown in FIG. 2, the gate G of the second transistor 46 is connected to the high-side control line 34ₕ for controlling operation of the high-side switch Sₕ. In some embodiments, and as shown in FIG. 2, the cascaded configuration of the HEMT 44 and the second transistor 46 is configured to default to an open circuit configuration with the control line 36ₕ, 36ₗ connected thereto being de-asserted. In other words, a positive control voltage may be applied to the high-side control line 34ₕ in order to cause the high-side switch Sₕ to be in a conductive state.

The high-side switch Sₕ is configured to selectively conduct current between the DC positive conductor VBUS₊ and an output conductor PHASE_A_OUT in response to assertion of a high-side control line 34ₕ. In the example circuit shown in FIG. 2, the high-side control line 34ₕ is connected to a gate terminal G of the second transistor 46, although other arrangements are possible in which the high-side control line 34ₕ is connected to a different terminal and/or a different device within the high-side switch Sₕ. A high-side driver 36ₕ within the controller 32 is configured to selectively assert the high-side control line 34ₕ, for example with a pulse width modulation (PWM) signal, to approximate an AC waveform on the output conductor PHASE_A_OUT.

The low-side switch Sₗ in the example switching circuit 40 shown in FIG. 2 includes a switching transistor 42, which is a depletion mode (D-Mode) gallium nitride (GaN) HEMT, connected directly between the output conductor PHASE_A_OUT and a DC negative conductor VBUS₋. Other types of HEMT may be used, such as a silicon carbide (SiC) transistor. The low-side switch Sₗ is configured to selectively conduct current between the output conductor PHASE_A_OUT the a DC negative conductor VBUS₋ in response to assertion of a low-side control line 34ₗ. In the example circuit shown in FIG. 2, the low-side control line 34ₗ is connected to a gate terminal G of the switching transistor 42, although other arrangements are possible in which the low-side control line 34ₗ is connected to a different terminal and/or a different device within the low-side switch Sₗ. A low-side driver 36ₗ within the controller 32 is configured to selectively assert the low-side control line 34ₗ, for example with a pulse width modulation (PWM) signal, to approximate an AC waveform on the output conductor PHASE_A_OUT. In some embodiments, such as the example shown in FIG. 2, the low-side control line 34ₗ may be asserted with a low voltage. In other words, the low-side switch Sₗ may be driven to a conductive state in response to a low or 0V control voltage on the low-side control line 34ₗ.

The present disclosure provides a switching circuit 40 using depletion mode switches, which are in a conductive state in the absence of a control signal, while also providing for safe-state operation with the output conductor PHASE_A_OUT conducted with a DC negative conductor VBUS₋ and isolated from a DC positive conductor VBUS₊ in the event of a loss of control signals 34ₕ, 34ᵢ. The switching circuit 40 may be used as a phase switch 30a, 30b, 30c of a motor drive 20, with the output conductor PHASE_A_OUT providing power to an electric motor 22. If the gates G of each of the transistors 42, 44, 46 in the switching circuit 40 are 0V with respect to their corresponding source terminals S, the switching circuit 40 provides a conductive path between the DC negative conductor VBUS₋ and the output conductor PHASE_A_OUT. Furthermore, when all the control signals 34ₕ, 34ₗ are in a low voltage state, the switching circuit 40 provides electrical continuity to conduct current between the DC negative conductor VBUS₋ and the output conductor PHASE_A_OUT while also providing electrical isolation, blocking current flow, between the DC positive conductor VBUS₊ and the output conductor PHASE_A_OUT.

The switching circuit 40 shown in FIG. 2 may be used as a phase switch, 30a, 30b, 30c in the motor drive 20 of FIG. 1, or in a motor drive with a different configuration, such as a different number of phases. Alternatively or additionally, the switching circuit 40, or portions thereof, may be used as an AC generator circuit to generate an AC waveform upon the output conductor for other applications, such as for providing AC power source to a load from a DC supply, or as part of a step-up or step-down DC/DC converter.

The foregoing description is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A switching circuit comprising:
a high-side switch configured to selectively conduct current between a DC positive conductor and an output conductor;
a low-side switch configured to selectively conduct current between the output conductor and a DC negative conductor; and
wherein at least one of the high-side switch or the low-side switch comprises a high-electron-mobility transistor (HEMT) and a second transistor in a cascaded configuration.

2. The switching circuit of claim 1, wherein the HEMT is a depletion-mode device that defaults to a conductive condition in the absence of a control voltage being applied to a gate thereof.

3. The switching circuit of claim 1, wherein each of the high-side switch and the low-side switch includes a depletion-mode HEMT device that defaults to a conductive condition in the absence of a control voltage being applied to a gate thereof.

4. The switching circuit of claim 3, wherein only one of the high-side switch or the low-side switch comprises a high-electron-mobility transistor (HEMT) and a second transistor in a cascaded configuration, and wherein the other one of the of the high-side switch or the low-side switch comprises a high-electron-mobility transistor (HEMT) connected directly between the output conductor and a corresponding one of the DC positive conductor or the DC negative conductor.

5. The switching circuit of claim 1, wherein the second transistor is a Silicon-based field effect transistor (Si-FET).

6. The switching circuit of claim 1, wherein the cascaded configuration includes a gate of the HEMT connected to the output conductor.

7. The switching circuit of claim 1, wherein the cascaded configuration includes a source terminal of the HEMT connected to a drain terminal of the second transistor.

8. The switching circuit of claim 7, wherein the cascaded configuration includes a drain terminal of the HEMT connected to the DC positive conductor, and a source terminal of the second transistor connected to the output conductor.

9. The switching circuit of claim 1, wherein the HEMT is a gallium nitride (GaN) transistor.

10. The switching circuit of claim 1, wherein the at least one of the high-side switch or the low-side switch is the high-side switch.

11. The switching circuit of claim 1, wherein the at least one of the high-side switch or the low-side switch is the low-side switch.

12. The switching circuit of claim 1, wherein the cascaded configuration includes a gate of the HEMT coupled to the output conductor, and a gate of the second transistor coupled to a control line for controlling operation of the at least one of the high-side switch or the low-side switch.

13. The switching circuit of claim 12, wherein the cascaded configuration of the HEMT and the second transistor is configured to default to an open circuit configuration with the control line being de-asserted.

14. A power inverter comprising the switching circuit of claim 1 to generate an AC waveform upon the output conductor.

15. A motor drive having a phase switch including the switching circuit of claim 1 to generate an AC waveform upon the output conductor.

16. A motor drive comprising:
a phase switch configured to generate an AC waveform upon an output conductor, the phase switch including:
a high-side switch configured to selectively conduct current between a DC positive conductor and the output conductor;
a low-side switch configured to selectively conduct current between the output conductor and a DC negative conductor; and
wherein at least one of the high-side switch or the low-side switch comprises a high-electron-mobility transistor (HEMT) and a second transistor in a cascaded configuration.

17. The motor drive of claim 16, wherein the HEMT is a depletion-mode device that defaults to a conductive condition in the absence of a control voltage being applied to a gate thereof.

18. The motor drive of claim 16, wherein each of the high-side switch and the low-side switch includes a depletion-mode HEMT device that defaults to a conductive condition in the absence of a control voltage being applied to a gate thereof.

19. The motor drive of claim 18, wherein only one of the high-side switch or the low-side switch comprises a high-electron-mobility transistor (HEMT) and a second transistor in a cascaded configuration, and wherein the other one of the of the high-side switch or the low-side switch comprises a high-electron-mobility transistor (HEMT) connected directly between the output conductor and a corresponding one of the DC positive conductor or the DC negative conductor.

20. The motor drive of claim 16, wherein the cascaded configuration includes a gate of the HEMT coupled to the output conductor, and a gate of the second transistor coupled to a control line for controlling operation of the at least one of the high-side switch or the low-side switch.
